(19) United States
(12) Patent Application Publication
(10) Pub. No.: US 2010/0164529 A1
(43) Pub. Date: Jul. 1, 2010

(54) SEMICONDUCTOR DEVICE TEST SYSTEM

(76) Inventor: Tsan-Fu HUNG, Changhua County (TW)

Correspondence Address: Muncy, Geissler, Olds & Lowe, PLLC, 4000 Legato Road, Suite 310, FAIRFAX, VA, 22033, US

(21) Appl. No.: 12/540,099

(22) Filed: Aug. 12, 2009

(30) Foreign Application Priority Data
Dec. 31, 2008 (TW) 097223946

(51) Int. Cl. G01R 31/26; G05B 11/01

(52) U.S. Cl. 324/765; 700/8

(57) ABSTRACT

A test system for semiconductor devices including a tester, a test station, a first controller, and one or more second controllers, is disclosed. The tester handles operations of the test system. The test station, coupled to the tester, receives test information from the tester via a transmission path, where the test station performs a test process to a semiconductor device under test according to the test information, and then provides a test result to the tester. The first controller, electronically connected to the test station, receives the test information. The second controllers, electronically connected to the test station, handles the test process of the test station, where each the second controller corresponds to one or more semiconductor device under test. The first controller broadcasts the test information to one or more second controllers and receives the test result from the second controllers through an infrared communication interface.

### CROSS REFERENCE TO RELATED APPLICATIONS

This Application claims priority of Taiwan Patent Application No. 097223946, filed on Dec. 31, 2008, the entirety of which is incorporated by reference herein.

### BACKGROUND OF THE INVENTION

1. Field of the Invention

The invention relates to a test system, and more particularly to a test system for semiconductor devices.

2. Description of the Related Art

With respect to current semiconductor technology, a test process must be implemented to dice on a wafer before the wafer is sent to a customer or installed on a product. At the back-end fabrication process, when the dice are still on a wafer, the dice are singularized, packaged, and burned in for testing. In another semiconductor process, when the dice are cut from a wafer, the dice are tested and burned in to generate “known good dice” before packaged. With respect to advanced semiconductor processes, a wafer level test process is provided, wherein dice on a wafer are burned in and tested.

For the back-end process as described, more advanced and efficient test systems for semiconductor devices may be desired.

### BRIEF SUMMARY OF THE INVENTION

An object of the present invention is to provide a test system for semiconductor devices.

Test systems for semiconductor devices are provided. An exemplary embodiment of a test system for semiconductor devices comprises a tester, a test station, a first controller, and one or more second controllers. The tester handles operations of the test system. The test station is coupled to the tester for receiving test information from the tester via a transmission path, wherein the test station performs a test process to a semiconductor device under test according to the test information, and then provides a test result to the tester. The first controller is electronically connected to the test station for receiving the test information. The second controllers are electronically connected to the test station for handling the test process of the test station, where each the second controller corresponds to one or more semiconductor device under test. The first controller broadcasts the test information to one or more second controllers and receives the test result from the second controllers through an infrared communication interface.

Another embodiment of a test system for semiconductor devices comprises a tester and a test station. The tester handles operations of the test system. The test station is coupled to the tester for receiving test information from the tester through an infrared communication interface to perform a test process to a semiconductor device under test according to the test information, and then provides a test result to the tester. The tester includes (a) a third control unit for handling operations of the tester; (b) a third infrared transmission unit coupled to the third control unit for transmitting the test information to the test station or receiving the test result from the test station through the infrared communication interface; (c) a wireless communication unit coupled to the third control unit for providing a communication interface between the tester and an external base station; (d) a third memory unit coupled to the third control unit for storing data or software required by the third control unit; (e) an input unit coupled to the third control unit for providing an input interface for the tester; (f) an alarm unit coupled to the third control unit for sending a notification message at a predetermined state; and (g) a display unit coupled to the third control unit for showing the test result.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic view of a semiconductor device test system according to the preferable embodiment of the present invention;

FIG. 2 is a schematic view of a test station according to the preferable embodiment of the present invention;

FIG. 3 is a schematic view of a first controller according to the preferable embodiment of the present invention;

FIG. 4 is a schematic view of second controllers according to the preferable embodiment of the present invention; and

FIG. 5 is a schematic view of a tester according to the preferable embodiment of the present invention.

### DETAILED DESCRIPTION OF THE INVENTION

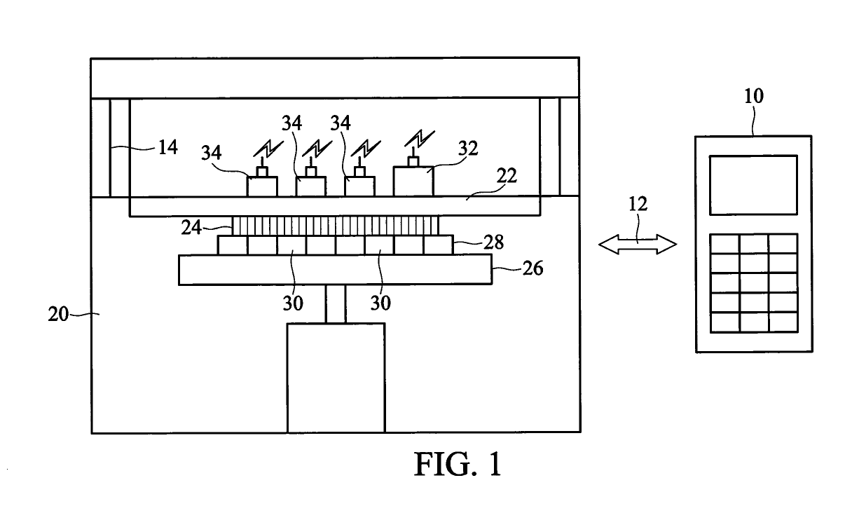

Several exemplary embodiments of the invention are described with reference to FIGS. 1 through 5, which generally relate to a test system for semiconductor devices. It is to be understood that the following disclosure provides various different embodiments as examples for implementing different features of the invention. Specific examples of components and arrangements are described in the following to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various described embodiments and/or configurations.

The invention discloses a test system for semiconductor devices. FIG. 1 is a schematic view of a test system for semiconductor devices 100 of the present invention. The test system for semiconductor devices 100 comprises a tester 10 and a test station 20. The tester 10 can be used to test general semiconductor devices, such as semiconductor wafers having dice thereon or singulated dice (packaged or unpackaged). In an exemplary embodiment, the tester 10 includes a portable device or a mobile terminal and communicates with the tester 20 via a transmission path 12 for transmitting test information. The transmission path 12 may include infrared transmission path or a physical/wireless transmission path. The test information generally includes data signals, address signals, control signals, state signals, test signals generated by the tester, and response signals generated by the dice under test.

Operations of the test system 100 are described. The tester 10 generates test data and transmits the test data to the test station 20 via the transmission path 12 for performing test process, such as electrical test or wafer probe. The probe 24 of the probe card 22 contacts the wafer 28 located on the platform 26. The platform 26 can support and move the wafer 28 with dice 30 under test. The test station 20 transmits the test data to the dice 30 of the wafer 28 via the probe 24 of the probe card 22 and receives response signals from the dice 30 in response to the test signal. The dice 30 can be typical integrated circuit chips, comprising, but is not limited to, memory chips, microprocessors or microcontrollers, signal processors, analog chips, application specified integrated circuits (ASIC), digital logic circuits, and so forth.

The first controller 32 includes an infrared transmission module and couples to the tester 10 via the connector 14 and the transmission path 12. The tester 10 provides test data for testing the dice 30 of the wafer 28 and transmits the test data to the first controller 32 via the transmission path 12. When the dice 30 have been tested, response data for the testing is transmitted to the tester 10 via the first controller 32.

The probe card 22 includes plural second controllers 34 with an infrared communication module. Thus, the first controller 32 can broadcast test data received from the tester 10 to the second controllers 34 by infrared communication interface. The received test data is then electronically transmitted from the second controllers 34 to the dice 30 via a conductive circuit (not shown) in the probe card 22. Response data generated by the dice 30 is provided from dice 30 to the tester 10 through the second controllers 34, the first controller 32, and the transmission 12.

The second controllers 34 can respectively control test processes of the dice 30, and each second controller 34 corresponds to one or multiple dice 30. The first controller 32 creates a flexible and extendable transmission interface between the first controller 32 and the tester 10 through the second controllers 34. For example, the number of the transmission channels between the tester 10 and the test station 20 is fixed so that the tester 10 can only test a predetermined number of dice test process. By changing the transmission interfaces between the first controller 32 and the second controllers 34 and adjusting the number of second controllers 34, the number of dice 30 can be increased without adding the number of transmission channels connecting to the tester 10.

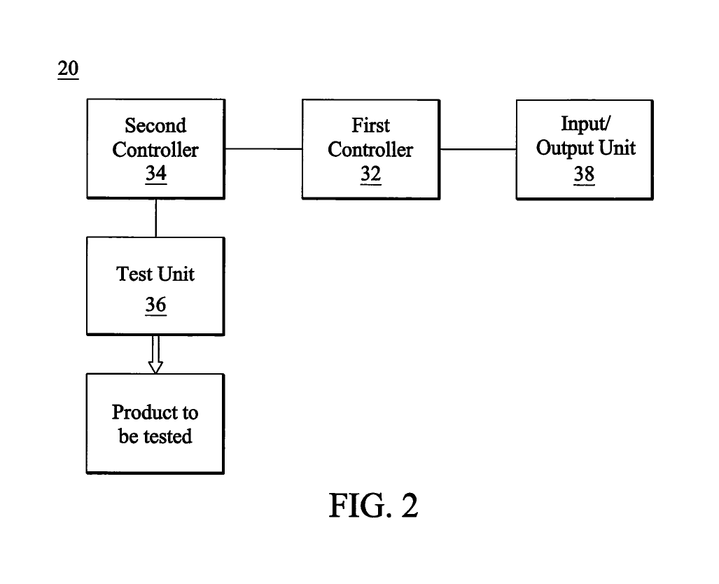

FIG. 2 is a schematic view of the test station 20 of the present invention. The test station 20 comprises a first controller 32, plural second controllers 34, a test unit 36, and an input/output unit 38. The first controller 32 handles operations of the test station 20. Further, the first controller 21 transmits information to the second controllers 34 via infrared communication interface for handling operations of the second controllers 34. The second controllers 34 correspond to one or multiple dice under test and transmit test instructions or information to the test unit 36 for performing a test process. The test unit 36 receives the test instructions, implements a test process to the dice under test, and transmits a test result to the second controllers 34. The second controllers 34 transmit the test result to the first controller 32 via infrared transmission. The first controller 32 transmits the test result to an external tester via the input/output unit 38. In an exemplary embodiment, the test unit 36 includes a probe card.

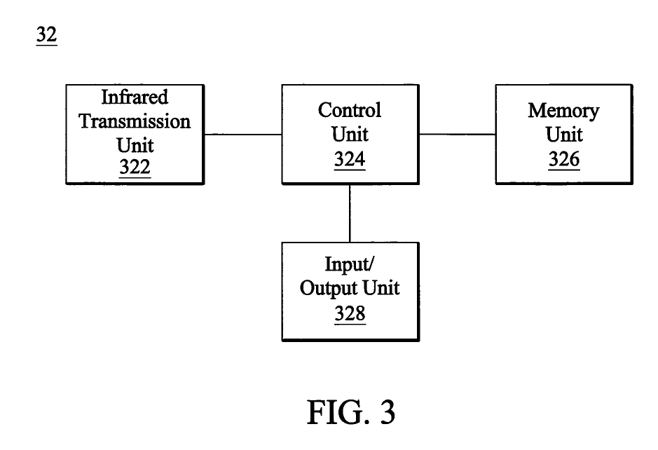

FIG. 3 is a schematic view of a first controller 32 according to the preferable embodiment of the present invention. Multiple functions of the first controller 32 can be integrated as an integrated circuit or multiple integrated circuits. The first controller 32 comprises an infrared transmission unit 322, a control unit 324, a memory unit 326, and an input/output unit 328. The infrared transmission unit 322 can transmit test signals to the second controllers 34 receive the test result from the second controllers 34 via the wireless transmission. The control unit 324 handles operations of the first controller 32. The control unit 324 includes a microprocessor operating under software control, a logic circuit or a combination thereof. The memory unit 326 stores data or software required by the control unit 324. The input/output unit 328 provides a physical input/output interface between the first controller 32 and the test station 20.

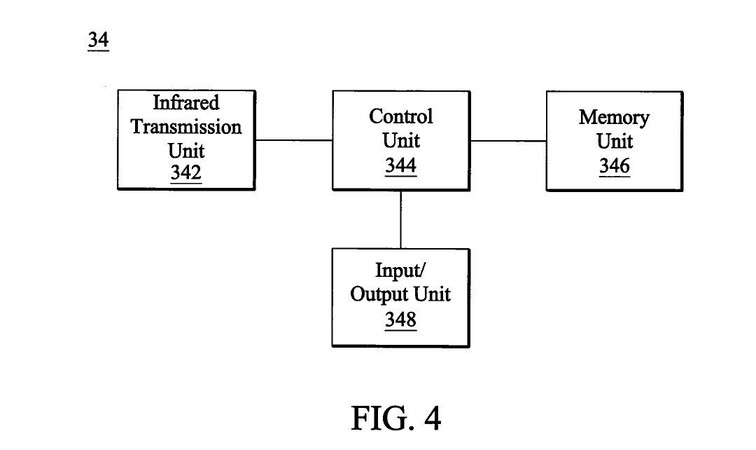

FIG. 4 is a schematic view of the second controllers 34 of the present invention. In an exemplary embodiment, the second controllers 34 may includes a control module capable of infrared transmission and multiple functions of which can be integrated as an integrated circuit or multiple integrated circuits. The first controllers 34 comprise an infrared transmission unit 342, a control unit 344, a memory unit 346, and a probe input/output unit 348. The infrared transmission unit 342 can transmit the test result to the first controller 32 or receive the test signals from the first controller 32 via the wireless transmission, such as infrared communication. The control unit 344 handles operations of the second controllers 34. The control unit 344 includes a microprocessor operating under software control, a logic circuit, or a combination thereof. The memory unit 346 stores data or software required by the control unit 344. The input/output unit 348 provides a physical input/output interface between the second controllers 34 and the probe 24.

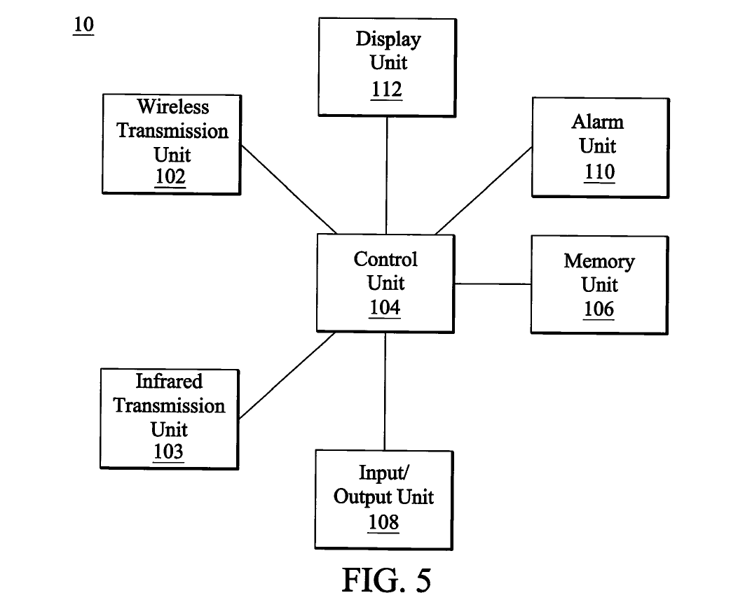

FIG. 5 is a schematic view of the tester 10 of the present invention. The tester 10 comprises a wireless transmission unit 102, an infrared transmission unit 103, a control unit 104, a memory unit 106, an input unit 108, an alarm unit 110, and a display unit 112. The wireless communication unit 102 transmits/receives wireless signals between the tester 10 and an external station (not shown). The infrared transmission unit 103 transmits/receives infrared signals between the tester 10 and the test station 20. The control unit 104 handles operations of the tester 10. The control unit 104 includes a microprocessor operating under software control, a logic circuit, or a combination thereof. The memory unit 106 stores data or software required by the control unit 106. The input unit 108 acts as an input interface of the tester 10. In an exemplary embodiment, the input unit 108 may includes a keyboard, a touch screen or a voice control device for inputting instructions. The alarm unit 110 sends a notification message at a predetermined state for reminding the user of the status of the tester 10. In an exemplary embodiment, the alarm unit 110 may be a speaker, a buzzer or a micromotor for generating text, audio or vibrating signals to notify the user the status of the tester 10. The display unit 112 provides a display function. In an exemplary embodiment, the tester 10 can display an operational interface with a graphical user interface (GUI) on the display unit 112 for providing a friendly operation interface. In an exemplary embodiment, the tester 10 comprises a portable device, such as a mobile terminal.

Operations of the test system for semiconductor devices 100 are described in the following. Test schedule information can be obtained by presetting test schedule information using input unit 108, accessing test schedule information stored in the memory unit 106 of the tester 10 or downloading test schedule information using the wireless communication unit 102. When a predetermined date and time is reached, the alarm unit 110 sends a notification message to the user.

Next, the tester 10 identifies the selected test station 20 to operate via the infrared communication unit 102 based on the test schedule information. Each test station 20 comprises an identification code. The tester 10 identifies the test station 20 corresponding to a test process and creates a communication interface for performing the test process. The tester 10 identifies the operable test station 20. If operational authority of the user and the test schedule information are allowed, the test station 20 can be identified and controlled.

When tester 10 identifies that test station 20 is allowed to operate, the tester 10 initializes the state of the test station 20 to adjust the first controller 32 in the test station 20 and the second controllers 34 to have identical operative state and creates a transmission protocol, such as frequency division multiple access (FDMA) or time division multiple access (TDMA), for setting up transmission between the first controller 32 and the second controllers 34. If the test station 20 has multiple first controllers 32, each of the first controllers 32 can be assigned corresponding second controllers to operation at different frequencies or times.

When the test station 20 is set, the tester 10 transmits test information or instructions to the test station 20 via the transmission path 12 for performing a test process. The first controller 32 broadcasts the test information or instructions to corresponding second controllers 34 before receiving the test information or instruction. The second controllers 34 transmit the test information to the dice 30 under test via the probe 24 of the probe card 22 for performing the test process.

The dice 30 which have been tested generate a test result in response to the test process and the test result is transmitted to corresponding second controllers 34 through the probe 24 and the conductive path (not shown) of the probe card 22. The second controllers 34 receiving the test results from the dice 30 transmits the test results to the first controller 32 via infrared transmission. Sequentially, through the transmission path the first controller 32 transmits the test results to the tester 10 for displaying the test results on the display unit 112 of the tester 10.

An embodiment of the test system for semiconductor devices tests semiconductor devices via wireless transmission so that the number of DUT (device under test) per operation of test stations can be increased. By changing the number of transmission interfaces between the first controller and the second controllers and adjusting the number of second controllers, the number of the dice under test can be increased without changing the number of transmission channels connected to the tester. If an input/output interface of the test station only provides 12 transmission channels (for 6 input channels and 6 output channels), the tester can only test 6 semiconductor devices per operation. The number of semiconductor devices under test per test operation can be increased by changing the proportion of the input channels to the output channels. For example, if the number of the input channels changes to 1, the remaining 11 transmission channels can serve as the output channels. In this case, the first controller receives test information from the input channel and broadcasts the test information to multiple second controllers via infrared transmission for performing a test process. The second controllers transmit a test result to the first controller and the first controller transmits the test result to the tester via the remaining 11 transmission channel. Thus, the number of semiconductor devices per test operation is increased.

Further, an embodiment of the test system for semiconductor devices transmits test information via infrared transmission without modulating transmission signals in general radio frequency range, such that radio frequency (RF) interference or antenna effect due to wireless transmissions may be reduced. Thus, this can improve testing quality for semiconductor devices, especially for semiconductor devices which may easily cause RF interference, such as RF chips.

Additionally, the tester of the present invention combines general testers and mobile terminals, which is more convenient, usable, and portable for users. Further, the tester can be used to communicate with other testers and transmit test information via mobile communication for communication between workers on the production line.

Methods and systems of the present disclosure, or certain aspects or portions of embodiments thereof, may take the form of a program code (i.e., instructions) embodied in media, such as floppy diskettes, CD-ROMS, hard drives, firmware, or any other machine-readable storage medium, wherein, when the program code is loaded into and executed by a machine, such as a computer, the machine becomes an apparatus for practicing embodiments of the disclosure. The methods and apparatus of the present disclosure may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for practicing and embodiment of the disclosure. When implemented on a general-purpose processor, the program code combines with the processor to provide a unique apparatus that operates analogously to specific logic circuits.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A test system for semiconductor devices, comprising:
a tester for handling operations of said test system;
a test station coupled to said tester for receiving test information from said tester via a transmission path, wherein said test station performs a test process to a semiconductor device under test according to said test information, and then provides a test result to said tester;
a first controller electronically connected to said test station for receiving said test information; and
one or more second controllers electronically connected to said test station for handling said test process of said test station, wherein each said second controller corresponds to one or more said semiconductor device under test,
wherein said first controller broadcasts said test information to one or more second controllers and receives said test result from said second controllers through an infrared communication interface.

2. The test system for semiconductor devices as claimed in claim 1, wherein said tester includes a portable device or a mobile terminal.

3. The test system for semiconductor devices as claimed in claim 1, wherein said test process includes an electrical test or a wafer probe.

4. The test system for semiconductor devices as claimed in claim 1, wherein said semiconductor device includes a semiconductor wafer having dice thereon.

5. The test system for semiconductor devices as claimed in claim 1, wherein said transmission path includes an infrared transmission path.

6. The test system for semiconductor devices as claimed in claim 1, wherein said test station includes a probe card for testing said semiconductor device.

7. The test system for semiconductor devices as claimed in claim 1, wherein said first controller comprises:
a first control unit for controlling operations of said first controller;
a first infrared transmission unit coupled to said first control unit for transmitting said test information to one or more said second controllers or receiving said test result from one or more said second controllers through said infrared communication interface;
a first memory unit coupled to said first control unit for storing data or software required by said first control unit; and
a first input/output unit coupled to said first control unit for providing a physical input/output interface between said first controller and said test station.

8. The test system for semiconductor devices as claimed in claim 1, wherein said second controller comprises:
a second control unit for controlling operations of said second controller;
a second infrared transmission unit coupled to said second control unit for transmitting said test result to said first controller or receiving said test information from said first controller through said infrared communication interface;
a second memory unit coupled to said second control unit for storing data or software required by said second control unit; and
a second input/output unit coupled to said second control unit for providing a physical input/output interface between said second controller and said semiconductor device.

9. The test system for semiconductor devices as claimed in claim 1, wherein said tester comprises:
a third control unit for controlling operations of said tester;
a third infrared transmission unit coupled to said third control unit for transmitting said test information to said test station or receiving said test result from said test station through said infrared communication interface;
a wireless communication unit coupled to said third control unit for providing a communication interface between said tester and an external base station;
a third memory unit coupled to said third control unit for storing data or software required by said third control unit;
an input unit coupled to said third control unit for providing an input interface for said tester;
an alarm unit coupled to said third control unit for sending a notification message at a predetermined state; and
a display unit coupled to said third control unit for showing said test result.

10. The test system for semiconductor devices as claimed in claim 9, wherein said input unit includes a keyboard, a touch screen or a voice control device.

11. The test system for semiconductor devices as claimed in claim 9, wherein said alarm unit includes a speaker, a buzzer or a micromotor.

12. The test system for semiconductor devices as claimed in claim 9, wherein said notification message includes text, audio or vibrating signals.

13. The test system for semiconductor devices as claimed in claim 9, wherein said tester acquires test schedule information through predetermining said test schedule information by said input unit, accessing said test schedule information stored in said third memory unit or downloading said test schedule information from said external base station.

14. The test system for semiconductor devices as claimed in claim 9, wherein said alarm unit sends said notification message based on said test schedule information stored in said third memory unit.

15. The test system for semiconductor devices as claimed in claim 9, wherein said tester identifies said test station through said third infrared transmission unit based on said test schedule information and user authority stored in said third memory unit.

16. A test system for semiconductor devices, comprising:
a tester for handling operations of said test system; and
a test station coupled to said tester for receiving test information from said tester through an infrared communication interface to perform a test process to a semiconductor device under test according to said test information, and then provides a test result to said tester, wherein said tester includes:
(a) a third control unit for handling operations of said tester;
(b) a third infrared transmission unit coupled to said third control unit for transmitting said test information to said test station or receiving said test result from said test station through said infrared communication interface;
(c) a wireless communication unit coupled to said third control unit for providing a communication interface between said tester and an external base station;
(d) a third memory unit coupled to said third control unit for storing data or software required by said third control unit;
(e) an input unit coupled to said third control unit for providing an input interface for said tester;
(f) an alarm unit coupled to said third control unit for sending a notification message at a predetermined state; and
(g) a display unit coupled to said third control unit for showing said test result.

17. The test system for semiconductor devices as claimed in claim 16, further comprising:
a first controller electronically connected to said test station for receiving said test information; and
one or more second controllers electronically connected to said test station for handling said test process of said test station, wherein each said second controllers corresponds to one or more said semiconductor devices under test.

18. The test system for semiconductor devices as claimed in claim 17, wherein said first controller broadcasts said test information to one or more second controllers and receives said test result from said second controllers through said infrared communication interface.

19. The test system for semiconductor devices as claimed in claim 16, wherein said tester acquires test schedule information through predetermining said test schedule information by said input unit, accessing said test schedule information stored in said third memory unit or downloading said test schedule information from said external base station.

20. The test system for semiconductor devices as claimed in claim 16, wherein said alarm unit sends said notification message based on said test schedule information stored in said third memory unit.

21. The test system for semiconductor devices as claimed in claim 16, wherein said tester identifies said test station through said third infrared transmission unit based on said test schedule information and user authority stored in said third memory unit.

22. The test system for semiconductor devices as claimed in claim 16, wherein said tester includes a portable device or a mobile terminal.

23. The test system for semiconductor devices as claimed in claim 16, wherein the test process includes an electrical test or a wafer probe.

24. The test system for semiconductor devices as claimed in claim 16, wherein the semiconductor device includes a semiconductor wafer having dice thereon.

25. The test system for semiconductor devices as claimed in claim 16, wherein the test station includes a probe card for testing said semiconductor device.

26. The test system for semiconductor devices as claimed in claim 17, wherein said first controller comprises:
a first control unit for controlling operations of said first controller;
a first infrared transmission unit coupled to said first control unit for transmitting said test information to one or more said second controllers or receiving said test result from one or more said second controllers through said infrared communication interface;
a first memory unit coupled to said first control unit for storing data or software required by said first control unit; and
a first input/output unit coupled to said first control unit for providing a physical input/output interface between said first controller and said test station.

27. The test system for semiconductor devices as claimed in claim 17, wherein said second controller comprises:
a second control unit for controlling operations of said second controller;
a second infrared transmission unit coupled to said second control unit for transmitting said test result to said first controller or receiving said test information from said first controller through said infrared communication interface;
a second memory unit coupled to said second control unit for storing data or software required by said second control unit; and
a second input/output unit coupled to said second control unit for providing a physical input/output interface between said second controller and said semiconductor device.
